(19) United States
(12) Patent Application Publication
(10) Pub. No.: US 2021/0356873 A1
(43) Pub. Date: Nov. 18, 2021

(54) METROLOGY METHOD AND APPARATUS THEREFOR

(71) Applicant: ASML NETHERLANDS B.V., Veldhoven (NL)

(72) Inventors: Arie Jeffrey DEN BOEF, Waalre (NL); Kaustuve BHATTACHARYYA, Veldhoven (NL); Kenji MORISAKI, Yokohama (JP); Simon Gijsbert MATHIJSSEN, Rosmalen (NL)

(73) Assignee: ASML NETHERLANDS B.V., Veldhoven (NL)

(21) Appl. No.: 17/277,583

(22) PCT Filed: Sep. 19, 2019
(86) PCT No.: PCT/EP2019/075143

§ 371 Date: Mar. 18, 2021

Related U.S. Application Data
(60) Provisional application No. 62/733,490, filed on Sep. 19, 2018.

(51) Int. Cl. G03F 7/20

(52) U.S. Cl. CPC G03F 7/70633; G03F 7/70683

(57) ABSTRACT

A method to measure a parameter of a manufacturing process, the method including illuminating a target with radiation, detecting scattered radiation from the target, and determining the parameter of interest from an asymmetry of the detected radiation.

### CROSS-REFERENCE TO RELATED APPLICATIONS

This application claims priority of U.S. application 62/733,490 which was filed on Sep. 19, 2019 and which is incorporated herein in its entirety by reference.

### BACKGROUND

Integrated circuits are often manufactured by means of a manufacturing process in which layers are formed on top of each other on a substrate by means of several process steps. One of the process steps is photolithography which may use electromagnetic radiation in the deep ultraviolet (DUV) spectral range or in the extreme ultraviolet (EUV) spectral range. The substrate is often a Silicon wafer. The smallest dimensions of the manufactured structures are in the nanometer range.

During the manufacturing process there is a need to inspect the manufactured structures and/or to measure characteristics of the manufactured structures. Suitable inspection and metrology apparatuses are known in the art. One of the known metrology apparatuses is a scatterometer and, for example, a dark field scatterometer.

Patent application publication US2016/0161864A1, patent application publication US2010/0328655A1 and patent application publication US2006/0066855A1 discus embodiments of a photolithographic apparatus and embodiments of a scatterometer. The cited documents are herein incorporated by reference in their entirety.

In a particular type of integrated circuit, such as a 3D-NAND memory device, a staircase profile is created. This staircase is needed to make contacts to the individual memory planes in the 3D-NAND device. This staircase is created by repeatedly removing a thin layer of resist followed by an etch step into a new bi-layer. This is repeated N times where N is the number of bi-layers. For many bi-layers the initial resist pattern needs to be very thick to about 10 μm. Moreover the lithography process for making this resist pattern is designed to create a sidewall angle of about 70 to 80 degrees, since this creates the best staircase profile.

Such device is depicted in FIG. 1, which shows a cross section in an actual device. The growth of layers and the processing direction, i.e. the way layers are built on top of each other, is in this example from bottom of FIG. 1, starting from element 106, toward the surface of the device, in this example the last layer depicted being the resist layer 102. Element 103 describes the succession of bi-layers. Elements 102 is a thick layer of resist having a thickness of 10 micrometers for example. Element 100 describes the typical opening, for example in the form of a V-groove, which is created in view of processing such device. The V-shape depicted in FIG. 1 is only an example. The angle characterizing the opening is 101, which is in an example of 20 degrees.

During the manufacturing of a 3D-NAND device, it is important that the relative alignment between the opening 100 in layer 102 and structures in layer 106, wherein layer 106 is a base layer, is precisely known. Such measure is known as overlay between opening 100 and structures in layer 106, for example structures such as lines 105. Overlay is known to be accurately measured with a metrology tool, as described in previously cited US patent applications. Overlay may be measured with an Image Based Overlay (IBO) tool or with a Diffraction Based Overlay (DBO) tool, the way these tools operate being well known and amply described in the state of the art.

A problem in measuring overlay with an IBO tool, due to the large distance between the two layers of interest (20 microns for example), is defocused images, i.e. if layer 102 is well in focus of the impinging illuminating radiation, structures in layer 106 are out of focus of the impinging illuminating radiation, which leads to an image of poor quality, and therefore to imprecision in calculating overlay. A solution is to measure the device twice, each time with the beam of radiation being focused first on the top layer, and then on the bottom layer. Such approach helps in improving measured overlay, but it leads, however, to increased time for metrology measurements, leading to decreased throughput in the overall metrology and manufacturing process.

### SUMMARY

It is an object of the present invention to provide a method to measure a parameter of a lithographic process, such as overlay, comprising a single image acquisition. The measured image is not limited to the image plane, which is a known element of metrology apparatus, well described in the state of the art, but the measured image may be formed also if an imaging sensor is placed in the pupil plane of a metrology apparatus, which is also known and well described in the state of the art. With a single image acquisition, which is suitable to allow accurate overlay measurements, the throughput of metrology is improved at least twofold.

According to the invention, a method to measure a parameter of a manufacturing process is disclosed, the method comprising illuminating a target with radiation, detecting the scattered radiation from the target, determining the parameter of interest from an asymmetry of the detected radiation. Further, according to the method, the asymmetry is calculated as the integral of the measured signal.

Further according to the invention, a method to measure a parameter of a manufacturing process is disclosed, the method comprising illuminating a target with radiation from a radiation source of an optical instrument, wherein the target is fabricated with the manufacturing process, wherein the radiation has a symmetry with regard to an axis, for example the optical axis of the optical instrument.

Further according to the invention, a target suitable for metrology is disclosed, the target comprising a first structure in a first layer, a second structure in a second layer, wherein the second structure comprises at least two lithographically formed gratings, and wherein the first structure comprises at least a first lithographically formed opening. Further, according to the target, the opening of the first structure is a V-groove. Further, according to the target, the gratings of the second structure are 2 longitudinal bars or gratings. Further according to the invention, a target for metrology is disclosed, the target comprising a V-groove structure.

### DESCRIPTION OF THE DRAWINGS

FIG. 2, a) to f), illustrates the method to measure a parameter of a lithographic process, such as overlay, using a metrology tool, for example a IBO tool or a DBO tool. FIGS. 2 a) to c) are schematics of the device described in FIG. 1. FIGS. 2 d) to f) illustrates the measured signal, in an example, measured signal which is obtained by illuminating the structure of FIG. 1 with radiation and detecting the scattered radiation from such target.

FIG. 2 a) illustrates a structure which does not comprise structures in layer 106. The scattered radiation, as detected on an image sensor is depicted in FIG. 2 d). With the addition of lines 105 (a two element grating) as shown in FIG. 2 b), the scattered signal changes to a form depicted in FIG. 2 e). The distance between gratings 105 is 5 micrometers, for example, as illustrated in FIG. 1 by element 104. The figures d) to f) in FIG. 2 are not to scale of the actual measured intensity, but are schematics illustrating the signal and the expected behavior of the measured signal. The signal in FIG. 2 e) shows additional satellite peaks, which are caused by the additional lines 105. Further, if there is mis-alignment between layer 102 and layer 106, therefore in case there is an overlay, illustrated by element 200 in FIG. 2 c), the measured signal, depicted in FIG. 2 f) may show an enhanced satellite peak and a diminished satellite peak. The enhancement or diminishment of the peaks is dependent on the direction on which overlay occurs. Furthermore, the size of the enhancement is proportional to the amount of overlay existing between the two layers. It is now recognized that the signal depicted in FIG. 2 e) is an example of the measured signal when there is no overlay present between the layers of interest.

### DESCRIPTION OF EXEMPLARY EMBODIMENTS

In an embodiment, the largest width of the opening 100, close to the surface of layer 102, is 5 microns. In an embodiment, the distance between the two elements 105 (element 104 in FIG. 1), is also 5 microns.

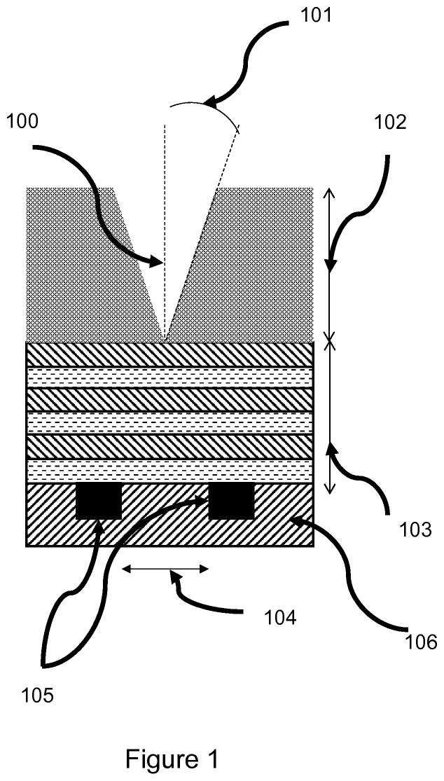

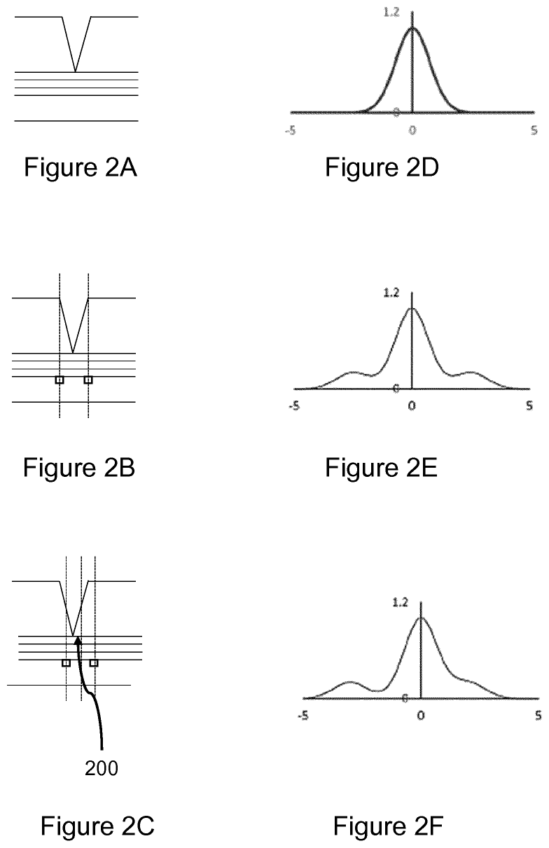

In an embodiment, the overlay is proportional with the asymmetry measured, as depicted for example in FIG. 2 f). In order to obtain the value of overlay, as expressed in nanometers, one needs to determine the proportionality factor between measured asymmetry and overlay. The proportionality factor, also known as K, may be eliminated by using known procedure from DBO metrology, wherein two targets are used, wherein a known bias d is applied between the top and bottom gratings, one target having positive bias d and the other target having negative bias −d. Any other methods as described in the state of the art may be used to determine or mitigate the presence of the proportionality factor K.

In an embodiment, the asymmetry of the measured signal may be determined by measuring the total area between the curve and the horizontal axis. In an embodiment, the asymmetry may be determined by measuring the integral of the measured signal with respect to the horizontal axis. In an embodiment, the asymmetry may be measured by first determining the position of each satellite peaks, and using as measured asymmetry the difference in values between the signals measured at those locations, i.e. at the locations where the peaks of the satellites are identified.

In an embodiment, the illuminating radiation is symmetrical, for example the averaged angle of incidence is 0. If non-symmetrical illumination may be used, one measured twice the same target from two directions with symmetrical angles (from opposite sides). In such non-symmetrical (oblique) illumination, the measured signal is asymmetric, even if there is no overlay. The asymmetry due to the oblique illumination may be removed by adding the two measured signals.

In an embodiment, a method is further expanded by measuring two targets: first target comprising no elements 105, therefore the signal is caused mainly the opening in layer 102, and second target comprising the target as depicted in FIG. 2 c). Further, the method if further expanded wherein the target of FIG. 2 c) is measure with a radiation at different wavelengths or polarizations. With such measurements it is mitigated the possible effects of an asymmetric illumination profile, or an asymmetry shape of the opening in layer 102.

It is to be noted that the embodiments of FIGS. 1 and 2 are examples. The skilled person may imagine modifications that have the same functionality and which are within the scope and spirit of the present invention.

1. A method to measure a parameter of a manufacturing process, the method comprising:
illuminating a target with radiation;
detecting scattered radiation from the target; and
determining the parameter from an asymmetry of a distribution of the detected radiation.

2. The method of claim 1, wherein the asymmetry is calculated as an integral of the distribution.

3. A method to measure a parameter of a manufacturing process, the method comprising:
illuminating a target with radiation from a radiation source of an optical instrument,
wherein the target is fabricated with the manufacturing process, and
wherein the radiation has a symmetry with regard to an axis.

4. A target suitable for metrology, the target comprising:
a first structure in a first layer; and
a second structure in a second layer underlying the first layer,
wherein the second structure comprises at least two lithographically formed elements of a grating, and
wherein the first structure comprises at least a first lithographically formed opening.

5. The target of claim 4, wherein the opening of the first structure is a V-groove.

6. The target of claim 4, wherein the elements of the grating of the second structure are 2 longitudinal bars.

7. A target for metrology, the target comprising a V-groove structure.

8. The target of claim 7, further comprising a grating underlying the V-groove structure.

9. The target of claim 8, wherein the grating is 2 longitudinal bars.

10. The method of claim 1, wherein the target comprises a groove structure with an underlying grating.

11. The method of claim 1, wherein the target comprises:
a first structure in a first layer; and
a second structure in a second layer underlying the first layer,
wherein the second structure comprises at least two lithographically formed elements of a grating, and
wherein the first structure comprises at least a first lithographically formed opening.

12. The method of claim 11, wherein the opening of the first structure is a V-groove.

13. The method of claim 11, wherein the elements of the grating of the second structure are 2 longitudinal bars.

14. The method of claim 3, wherein the target comprises a groove structure with an underlying grating.

15. The method of claim 3, wherein the target comprises:
a first structure in a first layer; and
a second structure in a second layer underlying the first layer,
wherein the second structure comprises at least two lithographically formed elements of a grating, and
wherein the first structure comprises at least a first lithographically formed opening.

16. The method of claim 15, wherein the opening of the first structure is a V-groove.

17. The method of claim 15, wherein the elements of the grating of the second structure are 2 longitudinal bars.
